(19) United States
(12) Patent Application Publication
(10) Pub. No.: US 2015/0301419 A1
(43) Pub. Date: Oct. 22, 2015

(54) ARRAY PLATE AND LIQUID CRYSTAL DISPLAY PANEL HAVING THE SAME

(71) Applicant: Shenzhen China Star Optoelectronics Technology Co., Ltd., Shenzhen, Guangdong (CN)

(72) Inventor: Yanfeng Fu, Shenzhen (CN)

(73) Assignee: Shenzhen China Star Optoelectronics Technology Co., Ltd., Shenzhen, Guangdong (CN)

(21) Appl. No.: 14/360,656

(22) PCT Filed: May 12, 2014
(86) PCT No.: PCT/CN2014/077205

§ 371 Date: May 27, 2014

(30) Foreign Application Priority Data
Apr. 16, 2014 (CN) 201410152726.7

(51) Int. Cl. G02F 1/1362; G02F 1/1335; G02F 1/1343; H01L 27/12; G02F 1/1368

(52) U.S. Cl. CPC G02F 1/136286; H01L 27/124; G02F 1/1368; G02F 1/134336; G02F 1/133514

(57) ABSTRACT

An LCD panel is disclosed. The LCD panel has an array plate and a CF plate. The array plate has a plurality of array common electrode lines, a pixel array, a plurality of gate lines, and a plurality of transparent conduct pads. The pixel array has a plurality of pixel units. The pixel units are arranged in rows and columns Each pixel unit has a pixel common electrode, and the pixel common electrodes of each row of pixel units are connected to the same array common electrode line. The gate lines are disposed between rows of pixel units. Each transparent conduct pad is disposed astride one of the gate lines and disposed between the adjacent pixel units of the same column of pixel units. The adjacent pixel units of the same column of pixel units are electrically connected with each other by one of the transparent conduct pads.

### BACKGROUND OF THE INVENTION

1. Field of Invention

The present invention relates to a liquid crystal display (LCD) panel, and more particularly, to an LCD panel, in which the potential uniformity between an array plate and a color film (CF) plate is improved so as to increase the uniformity of images displayed by the LCD panel.

2. Description of Prior Art

LCD is one of the most popular flat displays. There are a plurality of modes to display images, such as IPS (In Plane Switching liquid crystal) mode and HVA (High Vertical Alignment liquid crystal) mode.

A method to solve the lack of potential uniformity between an array plate and a CF plate in HVA mode is described below.

FIG. 1 is an illustration of a structure of an LCD panel of a prior art. FIG. 2 is a detailed illustration of a structure of a portion A of the LCD panel shown in FIG. 1. The LCD panel 10 comprises an array plate 20 and a CF plate 30.

The array plate 20 comprises a pixel array 23 which is constituted of a plurality of pixel units 27, a plurality of common electrode lines 21, and a plurality of first conduct points 25.

The CF plate 30 comprises a CF common electrode 31 and a plurality of second conduct points 32. The second conduct points 32 are electrically connected with the first conduct points 31.

Each pixel unit 27 comprises a pixel common electrode 22. The pixel common electrodes 22 of each row of pixel units 27 are connected to the same array common electrode lines 21, making the potential of the pixel common electrodes 22 of the same row of pixel units 27 more uniform.

The first conduct points 25 are disposed on a side of the array plate 20, and the array common electrode lines 21 are individually connected to at least one of the first conduct points 25. Meanwhile, the connection of the first conduct points 25 and the second conduct points 32 makes the CF common electrode 31 to be electrically connected with each of the array common electrode lines 21. Further, the potential uniformity between the CF common electrode 31 and each of the array common electrode lines 21 is increased.

As FIG. 1 shows, the adjacent pixel common electrodes 22 of the each row pixel units 27 are electrically connected by each of the array common electrode lines 21. However, the adjacent pixel common electrodes 22 of the each column pixel units 27 are electrically disconnected.

Since the potential difference is between the arrays of common electrode lines 21, then the potential uniformity is decreased between the CF common electrode 31 and each of the array common electrode lines 21. With LCD panels increasing in size, the potential uniformity between the pixel common electrode 22 of each of the pixel units 27 and the CF common electrode 31 has become important for improving the display performance. As mentioned above, the common electrodes of the same column of pixel units are electrically disconnected, mura (un-uniformity) of images will decrease the potential uniformity of the pixel units when applied in a larger LCD panel.

### SUMMARY OF THE INVENTION

The purpose of the present invention is to provide an LCD panel to improve the potential uniformity between an array plate of the LCD panel and a color film (CF) plate of the LCD panel.

To achieve above purpose, the present invention provides an array plate. The array plate comprises a plurality of array common electrode lines, a pixel array, a plurality of gate lines, and a plurality of transparent conduct pads.

The pixel array comprises a plurality of pixel units. The pixel units are arranged in rows and columns. Each pixel unit has a pixel common electrode, the pixel common electrodes of each row of pixel units are connected to the same array common electrode line. The pixel common electrodes of each column of pixel units are physically disconnected.

The gate lines are disposed between rows of pixel units.

Each transparent conduct pad is disposed astride one of the gate lines and disposed between adjacent pixel units of the same column of pixel units. The adjacent pixel units of the same column of pixel units are electrically connected with each other by one of the transparent conduct pads.

A plurality of conduct holes are disposed at two sides of each gate line. Each transparent conduct pad is electrically connected with the adjacent pixel units of the same column of pixel units by the conduct holes.

Each transparent conduct pad is disposed to be aligned to a position of each conduct hole of the adjacent pixel units of the same column of pixel units.

The array plate further comprises a plurality of first conduct points. Each first conduct point is electrically connected with at least one of the array common electrode lines directly. Each of the array common electrode lines is only electrically connected by the first conduct points.

To achieve above purpose, the present invention further provides an LCD panel. The LCD panel comprises an array plate and a CF plate. The array plate comprises a plurality of array common electrode lines, a pixel array, a plurality of gate lines, and a plurality of transparent conduct pads.

The pixel array comprises a plurality of pixel units. The pixel units are arranged in rows and columns. Each pixel unit has a pixel common electrode, and the pixel common electrodes of each row of pixel units are connected to the same array common electrode line. The pixel common electrodes of each column of pixel units are physically disconnected. The gate lines are disposed between rows of pixel units. Each transparent conduct pad is disposed astride one of the gate lines and disposed between adjacent pixel units of each column of pixel units. The adjacent pixel units of each column of pixel units are electrically connected with each other by one of the transparent conduct pads. A plurality of conduct holes are disposed at two sides of each gate line. Each transparent conduct pad is electrically connected with the adjacent pixel units of the same column of pixel units by the conduct holes.

Each transparent conduct pad is disposed to be aligned to a position of each conduct hole of the adjacent pixel units of the same column of pixel units.

The array plate further comprises a plurality of first conduct points. Each first conduct point is electrically connected with at least one of the array common electrode lines directly. Each of the array common electrode lines is only electrically connected by the first conduct points.

The CF plate further comprises a CF common electrode and a plurality of second conduct points. Each of the second conduct points and the CF common electrode are electrically connected. The first conduct points and the second conduct points are electrically connected.

Each first conduct point is disposed to be aligned to a position of each second conduct point.

To achieve above purpose, the present invention further provides an LCD panel. The LCD panel comprises an array plate and a CF plate. The array plate comprises a plurality of array common electrode lines, a pixel array, a plurality of gate lines, and a plurality of transparent conduct pads.

The pixel array comprises a plurality of pixel units. The pixel units are arranged in rows and columns. Each pixel unit has a pixel common electrode, and the pixel common electrodes of each row of pixel units are connected to the same array common electrode line. The pixel common electrodes of each column of pixel units are physically disconnected. The gate lines are disposed between rows of pixel units. Each transparent conduct pad is disposed astride one of the gate lines and disposed between adjacent pixel units of each column of pixel units. The adjacent pixel units of each column of pixel units are electrically connected with each other by one of the transparent conduct pads.

A plurality of conduct holes are disposed at two sides of each gate line. Each transparent conduct pad is electrically connected with the adjacent pixel units of the same column of pixel units by the conduct holes.

Each transparent conduct pad is disposed to be aligned to a position of each conduct hole of the adjacent pixel units of the same column of pixel units.

The array plate further comprises a plurality of first conduct points. Each first conduct point is electrically connected with at least one of the array common electrode lines directly. Each of the array common electrode lines is only electrically connected by the first conduct points.

The CF plate further comprises a CF common electrode and a plurality of second conduct points. Each of the second conduct points and the CF common electrode are electrically connected. The first conduct points and the second conduct points are electrically connected.

Each first conduct point is disposed to be aligned to a position of each second conduct point.

The present invention has the advantage of improving the potential uniformity between an array plate of the LCD panel and a color film (CF) plate of the LCD panel by disposing the transparent conduct pads to connect each column of pixel units. This increases the uniformity of the display images and the quality of the LCD panel.

### BRIEF DESCRIPTION OF THE DRAWINGS

FIG. 1 is a drawing of a structure of an LCD panel of a prior art.

FIG. 2 is a detailed drawing of a structure of a portion A of FIG. 1.

FIG. 3 is a drawing of a structure of an LCD panel of the present invention.

FIG. 4 is a detailed drawing of a structure of a portion B of FIG. 3.

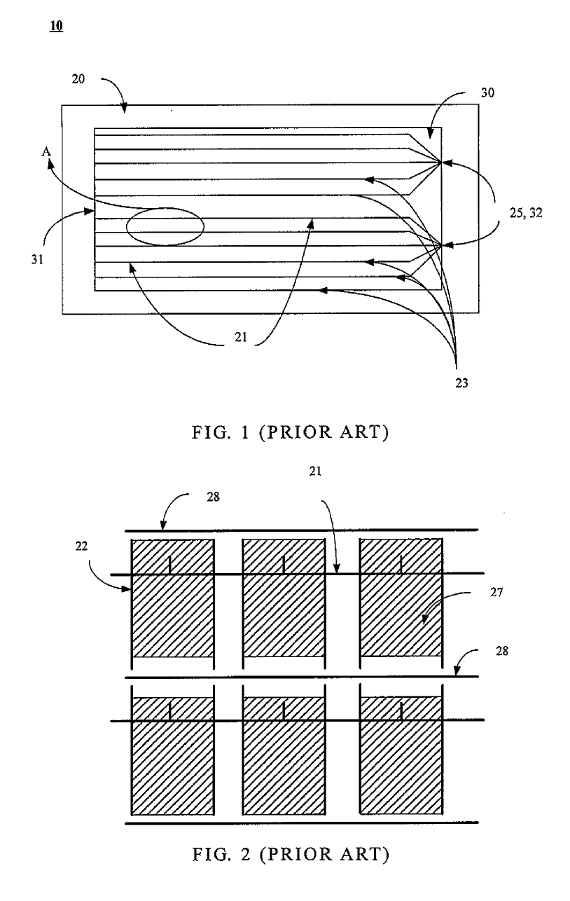

### DETAILED DESCRIPTION OF THE PREFERRED EMBODIMENTS

The following description of every embodiment, with reference to the accompanying drawings, is used to exemplify a specific embodiment which may be carried out in the present invention. Directional terms mentioned in the present invention, such as “top”, “bottom”, “front”, “back”, “left”, “right”, “inside”, “outside”, “side” etc., are only used with reference to the orientation of the accompanying drawings. Therefore, the used directional terms are intended to illustrate, but not to limit, the present invention. In the drawings, components having similar structures are denoted by the same numerals.

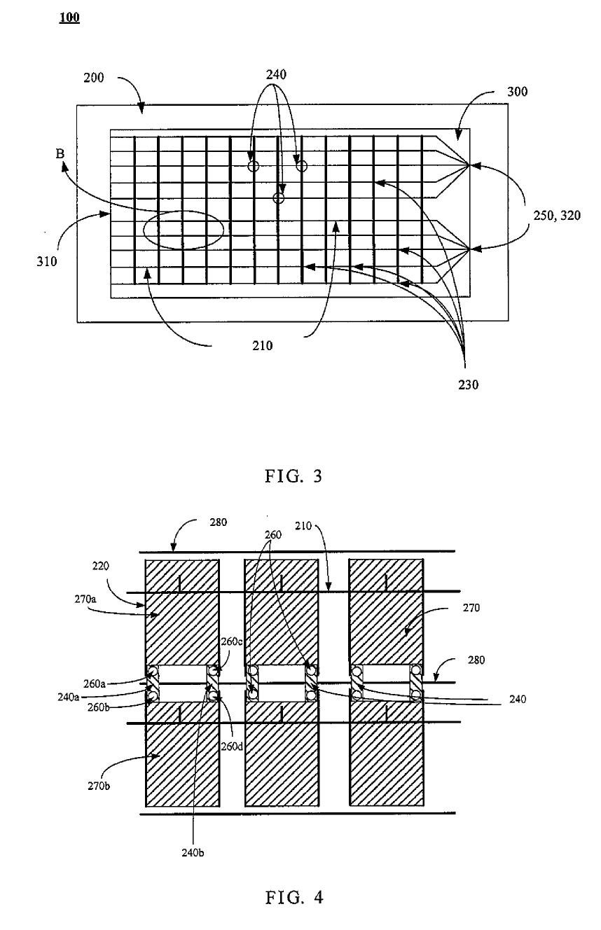

FIG. 3 is a drawing of a structure of an LCD panel of the present invention. FIG. 4 is a detailed drawing of a structure of a portion B of FIG. 3. An LCD panel 100 comprises an array plate 200 and a CF plate 300. The array plate 200 comprises a plurality of array common electrode lines 210, a pixel array 230, a plurality of gate lines 280, a plurality of transparent conduct pads 240, and a plurality of first conduct points 250.

The pixel array 230 comprises a plurality of pixel units 270. The pixel units 270 are arranged in rows and columns to form a pixel array 230. Each pixel unit 270 comprises a pixel common electrode 220. The pixel common electrodes 220 of each row of pixel units 270 are connected to the same array common electrode line 210. The pixel common electrodes 220 of each column of pixel units 270 are physically disconnected. In other words, the pixel common electrodes 220 of each row of pixel units 270 are electrically connected to each other. However, the pixel common electrodes 220 of each column of pixel units 270 are electrically disconnected from each other.

Each of the gate lines 280 are disposed between rows of pixel units 270. Generally, the gate lines 280 and the array common electrode lines are disposed parallel to each other.

Generally, the first conduct points 250 are disposed on either side of the array plate 200. The first conduct points are usually disposed in an overlap between the array plate 200 and the CF plate 300. Each first conduct point is electrically independent or electrically connected with the others. As FIG. 3 shows, every four array common electrode lines 210 are connected to one first conduct point 250. However, this embodiment is not restricted to only four array common electrode lines 210 being connected with one first conduct point 250. In other words, one first conduct point 250 could be connected with at least one array common electrode lines 210. Hence, the array common electrode lines 210 are electrically connected with each other by the first conduct points 250.

As mentioned above, the pixel common electrodes 220 of each column of pixel units 270 are not connected with each other directly. But, with the disposition of the transparent conduct pads 240, each of which is disposed astride one of the gate lines 280 and disposed between the adjacent pixel units 270 of the same column of pixel units, the adjacent pixel units 270 of the same column of pixel units are electrically connected with each other by one of the transparent conduct pads 240. The transparent conduct pads are made of indium tin oxide (ITO) or zinc tin oxide (ZTO).

The CF plate 300 further comprises a CF common electrode 310 and a plurality of second conduct points 320. Each of the second conduct point 320 and the CF common electrode 310 are electrically connected. The first conduct points 250 and the second conduct points 320 are electrically connected. The CF common electrode 310 and all array common electrode lines 210 are directly electrically connected by the first conduct points 250 and the second conduct points 320. Each first conduct point is disposed to be aligned to a position of each second conduct point.

In the present invention, the pixel common electrode 220 of each pixel units 270 could be electrically connected with the pixel common electrode 220 of an adjacent pixel unit 270 (in the same row or the same column) by providing the transparent conduct pad 240, so as to make the common electrodes be an conductive net, thereby increasing the potential uniformity between the pixel common electrode 220 of each pixel unit 270 and the CF common electrode 310 of the CF plate 300.

A plurality of conduct holes 260 are disposed at two sides of each gate line 280. Each transparent conduct pad 240 and the adjacent pixel units 270 of the same column of pixel units are electrically connected by the conduct holes 260. In the embodiment of the present invention, each of the adjacent pixel units (270a, 270b) in the same column has two conduct holes (260a, 260c for 270a; 260b, 260d for 270b), the pixel common electrodes (220a, 220b) of the pixel units (270a, 270b) are connected by one or two of the transparent conduct pads (240a, 240b). In other words, the transparent conduct pad 240a contacts the conduct holes (260a, 260b) so as to be electrically connected with the pixel common electrodes (220a, 220b) of the pixel units (270a, 270b), the transparent conduct pad 240b contacts the conduct holes (260c, 260d) so as to be electrically connected with the pixel common electrodes (220a, 220b) of the pixel units (270a, 270b).

Each transparent conduct pad 240 is disposed to be aligned to the positions of the adjacent conduct holes 260 of the same column of pixel units. After the conduct holes 260 are formed, by adjusting the design of a mask for fabricating a transparent conduct layer over the array plate, the transparent conduct pads can be fabricated at the same time as the transparent conduct layer. No extra process is needed.

In the present invention, by disposing transparent conduct pads on the existing array structure to be connected with the pixel common electrodes of the adjacent pixel units of each column of pixel units, the potential uniformity between an array plate and a CF plate is improved. This increases the uniformity of the display images and the quality of the LCD panel.

Although the present invention has been disclosed as preferred embodiments, the foregoing preferred embodiments are not intended to limit the present invention. Those of ordinary skill in the art, without departing from the spirit and scope of the present invention, can make various kinds of modifications and variations to the present invention. Therefore, the scope of the claims of the present invention must be defined.

What is claimed is:

1. An array plate comprising:
a plurality of array common electrode lines;
a pixel array comprising a plurality of pixel units, the pixel units being arranged in rows and columns, and each pixel unit having a pixel common electrode, the pixel common electrodes of each row of pixel units being connected to the same array common electrode line, the pixel common electrodes of each column of pixel units are physically disconnected;
a plurality of gate lines disposed between rows of pixel units; and
a plurality of transparent conduct pads, each transparent conduct pad being disposed astride one of the gate lines and disposed between the adjacent pixel units of the same column of pixel units, and adjacent pixel units of the same column of pixel units being electrically connected with each other by one of the transparent conduct pads.

2. The array plate according to claim 1, wherein a plurality of conduct holes are disposed at two sides of each gate line, each transparent conduct pad is electrically connected with the adjacent pixel units of the same column of pixel units by the conduct holes.

3. The array plate according to claim 2, wherein each transparent conduct pad is disposed to be aligned to a position of each conduct hole of the adjacent pixel units of the same column of pixel units.

4. The array plate according to claim 1, wherein the array plate further comprises a plurality of first conduct points, each first conduct point is electrically connected with at least one of the array common electrode lines directly, and each of the array common electrode lines is only electrically connected by the first conduct points.

5. An LCD panel comprising a CF plate and an array plate, the array plate comprising:
a plurality of array common electrode lines;
a pixel array comprising a plurality of pixel units, the pixel units being arranged in rows and columns, and each pixel unit having a pixel common electrode, the pixel common electrodes of each row of pixel units being connected to the same array common electrode line, the pixel common electrodes of each column of pixel units are physically disconnected;
a plurality of gate lines, disposed between rows of pixel units; and
a plurality of transparent conduct pads, each transparent conduct pad being disposed astride one of the gate lines and disposed between the adjacent pixel units of each column of pixel units, the adjacent pixel units of the same column of pixel units being electrically connected with each other by one of the transparent conduct pads.

6. The LCD panel according to claim 5, wherein a plurality of conduct holes are disposed at two sides of each gate line, each transparent conduct pad is electrically connected with the adjacent pixel units of the same column of pixel units by the conduct holes.

7. The LCD panel according to claim 6, wherein each transparent conduct pad is disposed according to be aligned to a position of each conduct hole of the adjacent pixel units of the same column of pixel units.

8. The LCD panel according to claim 5, wherein the array plate further comprises a plurality of first conduct points, each first conduct point is electrically connected with at least one of the array common electrode lines directly, and each of the array common electrode lines is only electrically connected by the first conduct points.

9. The LCD panel according to claim 8, wherein the CF plate further comprises a CF common electrode and a plurality of second conduct points, each of the second conduct points and the CF common electrode are electrically connected, and the first conduct points and the second conduct points are electrically connected.

10. The LCD panel according to claim 9, wherein each first conduct point is disposed to be aligned to a position of each second conduct point.

11. An LCD panel comprising a CF plate and an array plate, the array plate comprising:
a plurality of array common electrode lines;
a pixel array comprising a plurality of pixel units, the pixel units being arranged in rows and columns, and each pixel unit having a pixel common electrode, the pixel common electrodes of each row of pixel units being connected to the same array common electrode line, the pixel common electrodes of each column of pixel units are physically disconnected;
a plurality of gate lines, disposed between rows of pixel units; and
a plurality of transparent conduct pads, each transparent conduct pad being disposed astride one of the gate lines and disposed between the adjacent pixel units of each column of pixel units, the adjacent pixel units of the same column of pixel units being electrically connected with each other by one of the transparent conduct pads, and wherein a plurality of conduct holes are disposed at two sides of each gate line, each transparent conduct pad is electrically connected with the adjacent pixel units of the same column of pixel units by the conduct holes.

12. The LCD panel according to claim 10, wherein each transparent conduct pad is disposed according to be aligned to a position of each conduct hole of the adjacent pixel units of the same column of pixel units.

13. The LCD panel according to claim 10, wherein the array plate further comprises a plurality of first conduct points, each first conduct point is electrically connected with at least one of the array common electrode lines directly, and each of the array common electrode lines is only electrically connected by the first conduct points.

14. The LCD panel according to claim 13, wherein the CF plate further comprises a CF common electrode and a plurality of second conduct points, each of the second conduct points and the CF common electrode are electrically connected, and the first conduct points and the second conduct points are electrically connected.

15. The LCD panel according to claim 14, wherein each first conduct point is disposed to be aligned to a position of each second conduct point.
